(19) United States
(12) Patent Application Publication
(10) Pub. No.: US 2020/0088777 A1
(43) Pub. Date: Mar. 19, 2020

(54) PARASITIC EMULATOR FOR TESTING LIGHTING AND ELECTRIC BRAKE CIRCUITS ON TRAVEL AND FIFTH-WHEEL TRAILERS

(71) Applicants: Jay William Marshall, Orem, UT (US); Joseph Clair Eaton, Orem, UT (US)

(72) Inventors: Jay William Marshall, Orem, UT (US); Joseph Clair Eaton, Orem, UT (US)

(21) Appl. No.: 16/571,101

(22) Filed: Sep. 14, 2019

Related U.S. Application Data
(60) Provisional application No. 62/765,811, filed on Sep. 14, 2018.

(51) Int. Cl. G01R 31/00; G01R 19/165; G01R 31/385; G01R 1/02; G01R 1/04

(52) U.S. Cl. CPC G01R 31/006; G01R 19/16523; H01R 24/76; G01R 1/025; G01R 1/0416; G01R 31/385

(57) ABSTRACT

A compact and lightweight emulator is provided for parasitic testing individual lighting circuits and the electric brake circuit of travel trailers and fifth-wheel trailers, which are equipped with an on-board rechargeable battery. The emulator is equipped with a flasher circuit that, when activated, flashes the stop/turn lights on the trailer simultaneously in an emergency flasher mode. The emulator includes a housing, which incorporates a 7-blade receptacle for a trailer electrical plug, a digital voltmeter, a circuit selector switch, a keyed ON-OFF switch, which selectively sends power from the trailer battery to device circuitry, and a pair of external terminals, which can be connected to leads from an electrical charger in order to recharge the trailer's on-board battery.

### RELATED APPLICATION

This application has a priority date based on the filing of Provisional Application No. 62/765,811 on Sep. 14, 2018.

### BACKGROUND OF THE INVENTION

### 1. Field of the Invention

This invention relates generally to apparatus for the testing of electrical circuits on road-going trailers and, more particularly, to a parasitic apparatus for the solo testing (i.e., sans an assistant) of lighting and brake circuits on trailers, using the trailer's on-board battery for power, and without the need to hook up a tow vehicle to the trailer for the testing procedure.

### 2. Description of Related Art

Trailer electrical systems are exposed to a harsh environment. Trailers are typically stored in the open, so they are continually exposed to the elements.

Exposure to sunlight, heat, cold, wind, rain, snow and changes in humidity levels is not kind to electrical systems. In addition, when on the road and it is raining or snowing, trailers constantly receive spray from the towing vehicle. Furthermore, trailers generally have rather primitive suspension systems because it is illegal for human passengers to ride in them while they are being towed. Thus, light filaments are subject to vibration levels that passenger vehicles seldom experience. Consequently, lighting and electric braking systems on trailers are prone to failure. As inoperable electric braking and lighting systems are both dangerous and illegal, these systems should be tested every time that a trailer is towed on the open road.

The conventional method used to test braking and lighting circuits is to connect the trailer to the tow vehicle and have one person operate the switches of the various lighting circuits while another person verifies that the physical lights turn on or flash and that the electric braking circuit is functional. Although it is possible for a single person to check the lighting and braking circuits, that person will need a pole held against the brake pedal by the seat back to check brake lights. In addition, that single individual will need to leave the driver's seat and walk around the trailer several times in order to check functionality of brake lights, tail lights, running lights, right and left turn-signal lights, and the electric braking circuit. Though not difficult, the single person method takes considerably more time to complete the task.

A number of devices, which are listed below in ascending order of their priority dates, have been designed which enable a single person to perform lighting circuit tests without a need to connect the trailer to the tow vehicle. Each of these devices requires the use of an on-board, 12-volt battery that is used to power the circuits being tested. As a general rule, the battery must be purchased separately from the device.

US Patent Publication 2010/0237875 discloses a portable diagnostic device for checking electrical signaling systems of, for example, tractors and their trailers. The device has several receptacles for connection to a corresponding receptacle or pin connector of a trailer. One electrical circuit includes switches for energizing individual signaling or other circuits of the trailer individually, and indicating lamps and/or horns for annunciating circuit operability. The device, which is contained on a wheeled stand, has its own power supply and circuit overcurrent protective devices, and is thus independent.

U.S. Pat. No. 8,947,096 discloses a portable, self-contained device for testing the full cycle of trailer light modes without additional manual actuation by the user and for identifying where and what type of specific error occurred, if any are detected. The inventive device generally comprises a compact portable housing with a fixedly attached handle and a removable housing top. Within the compact portable housing is a self-contained, rechargeable 12 volt power source to power all functionality over a sustained period of time. Also within the compact portable housing is a light mode control means that allows the device to cycle through multiple light modes for testing, and an error detection analysis means that indicates where and what type of fault is detected. The outside surface of the compact portable housing contains an on/off switch means, a light mode selector switch to select from individual light modes or a cycle mode that rotates through all light modes at a predetermined interval, and fault detection indicators to indicate when, where, and what type of fault has been detected. Attached to a side of the housing is a connection port for connecting the device to a trailer light wiring harness.

US Patent Publication No. 2013/0229185 discloses a trailer light tester that includes a 7-way plug that is inserted into and connected to a trailer to check a plurality of various lighting circuits on the trailer, an elongated casing and a turning and stop light switch that is disposed on the elongated casing. The trailer light tester also includes a taillight and marker light switch that is disposed on the elongated casing, a rechargeable battery that powers the elongated casing and a plurality of circuit breakers that are housed in the interior of the elongated casing and protect the trailer light tester against a short or damage from an excessive amount of current.

Each of the three related art references described above utilizes a battery in the tester unit, itself. A 12-volt, 9 Ah sealed lead-acid battery weighs at least 2.7 kg (about 6 pounds). Thus, the inclusion of such a battery in a light and circuit testing device can easily result in a total device weight of nearly 4.5 kg (about 10 pounds). This is especially true if recharging circuitry for the included battery is also included in the testing device. Not only does a testing device which incorporates an on-board battery heavy, such devices are typically sold and shipped without the battery installed in the device. Thus, the buyer must also purchase and install a battery in the testing device. Given that portable testing devices can cost $200 or more at retail, and a 12V lead-acid battery to power the device can cost up to $100, depending on the type and size of the battery, it is not uncommon for the total retail cost of the testing device and the required battery to approach or exceed $300. It should also be mentioned that 12-volt lithium-ion battery packs, which are beginning to see use in automotive applications, are typically even more expensive than lead-acid batteries.

In spite of the high cost of devices for the testing of trailer lighting circuits, such prior art devices are short on functionality. Typically, there is no capability for the testing of electric brake circuits. In addition, although such testing devices are able to test individual turn signal circuits, they are unable to control the turn signal lights in a safety flasher mode. Consequently, if the need arises to temporarily park a trailer at the side of a highway, there is no provision to activate an emergency flasher circuit.

### SUMMARY OF THE INVENTION

The present invention provides a lightweight device that not only tests individual lighting circuits, but also enables the testing operator to verify that the trailer brakes are applied when the electric braking circuit is activated. The device is designed to test the electrical circuits of any trailer which is equipped with an on-board battery. For at least fifty years, travel trailers and fifth-wheel trailers have been equipped with their own on-board rechargeable battery, which is used not only to power the trailer's running lights, tail lights, brake lights, turn indicator lights and electric brake circuits, but also to power various other on-board electrical circuits which used when the trailer is occupied. Such other circuits may include interior lighting circuits, heater fans, and water pumps. Typically, battery power is not used to power resistance-wired heaters, air conditioners and refrigerators, as such appliances draw too much power for extended battery operation. In order to minimize weight and cost of the testing device, the testing device connects to the trailer's on-board battery through the trailer's electrical connector plug. Tests can then be performed parasitically, using the trailer's on-board battery to individually power the lighting and electric braking circuits. In addition, the lightweight testing device also is equipped with a flasher circuit. When the flasher circuit is activated, the stop/turn lights on the trailer flash simultaneously. Most trailer batteries, when fully charged, have sufficient stored power to operate the stop/turn signal lights for up to 36 hours, depending on the ampere-hour rating and condition of the battery. By eliminating the need for a battery within the testing device itself, the weight of the testing device can be dramatically reduced to 0.7 kg (about 1.5 lbs.) or less without any decrease in functionality. The lack of an electro-chemical storage battery within the testing device, itself, is a major distinguishing feature of the testing device of the present invention. The manufacturing cost of such a parasitic testing device can be reduced considerably.

The parasitic circuit tester includes a housing, a 7-way RV-type receptacle for a trailer electrical plug mounted on an exterior surface of the housing, a circuit selector switch mounted on an exterior surface of the housing, a digital voltmeter mounted on an exterior surface of the housing, a keyed ON-OFF switch mounted on an exterior surface of the housing which selectively sends power from the trailer battery to the circuit selector switch and to the digital voltmeter, and a pair of terminals mounted on an exterior surface of the housing, one of which is connected to the negative terminal of the trailer battery whenever the trailer electrical plug engages the 7-way receptacle, and the other of which is connected to the positive terminal of the trailer battery when the keyed ON-OFF switch in the ON position. The circuit selector switch has the following positions: OFF; backup light circuit; electric brake circuit; tail/marker light circuit; and brake and left/right turn indicator light circuit. An automotive electronic or thermal flasher module is installed within the housing, so that when the brake and left/right turn indicator light circuit is selected with the circuit selector switch, the trailer light bulbs for the brake and left/right turn indicator circuit will flash simultaneously. Thus, the brake and left/right turn indicator lights are tested in an emergency flasher mode, which can remain activated if the trailer needs to be parked at the side of the road disconnected from the tow vehicle. Power from the on-board trailer battery can provide power to activate the brake and left/right turn indicator lights in the emergency flasher mode for up to 36 hours. The trailer battery can be charged by connecting positive and negative charger leads to the respective positive and negative terminals which are mounted on the exterior surface of the housing. The digital voltmeter enables an individual who is performing a circuit testing sequence to monitor the voltage drop for each selected trailer circuit. If initial readings are taken for each fully working circuit, the individual will know that a circuit has a fault when subsequent readings deviate from those initial readings. All circuit connections are made within the housing. The housing is intended to be permanently mounted to the trailer. A preferred mounting location is the trailer tongue proximate the tongue coupler.

### BRIEF DESCRIPTION OF THE DRAWINGS

FIG. 1 is a perspective view of a standard housing used to fabricate the invention;

FIG. 2 is a front elevational view of the parasitic emulator of the present invention;

FIG. 3 is a top plan view of the parasitic emulator of FIG. 2;

FIG. 4 is a left side elevational view of the parasitic emulator of FIG. 2;

FIG. 5 is a right side elevational view of the parasitic emulator of FIG. 2; and

FIG. 6 is a circuit schematic diagram for the parasitic emulator.

### DETAILED DESCRIPTION OF THE PREFERRED EMBODIMENT

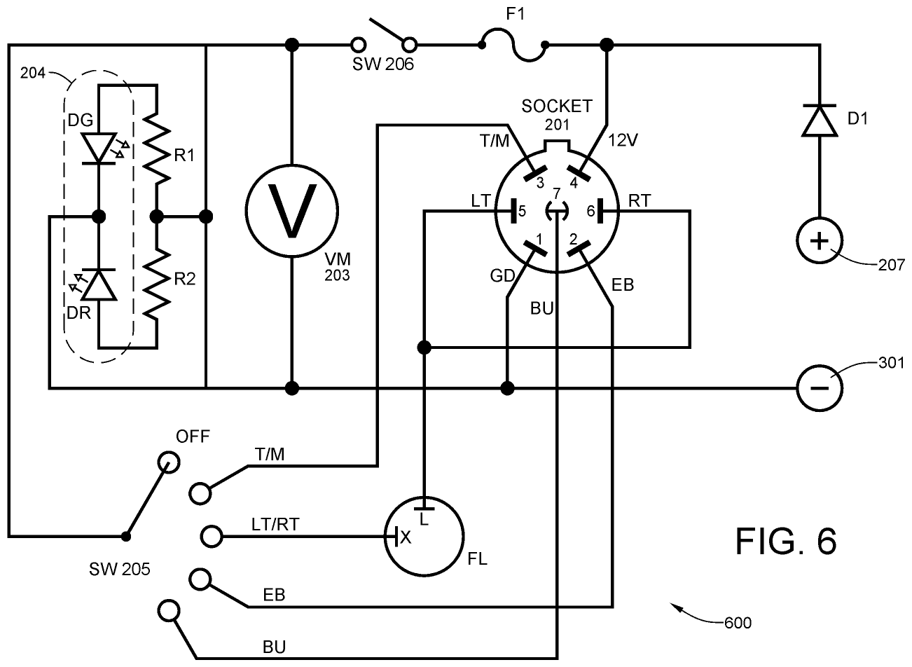

The parasitic emulator will now be described with reference to the attached drawing figures. It should be understood that the drawings are intended to be merely illustrative of the invention, and that the invention is to be defined, primarily, by the circuit schematic diagram of FIG. 6 and the attached claims, rather than by the physical appearance of the housing. The emulator is considered to be parasitic because it lacks its own power supply and must rely on an external power source. When testing the electrical circuits of trailers equipped with an on-board battery, the emulator uses the trailer battery to effectuate the testing process. The device is considered an emulator because it emulates the electrical functions of a towing vehicle in the testing of trailer electrical circuits.

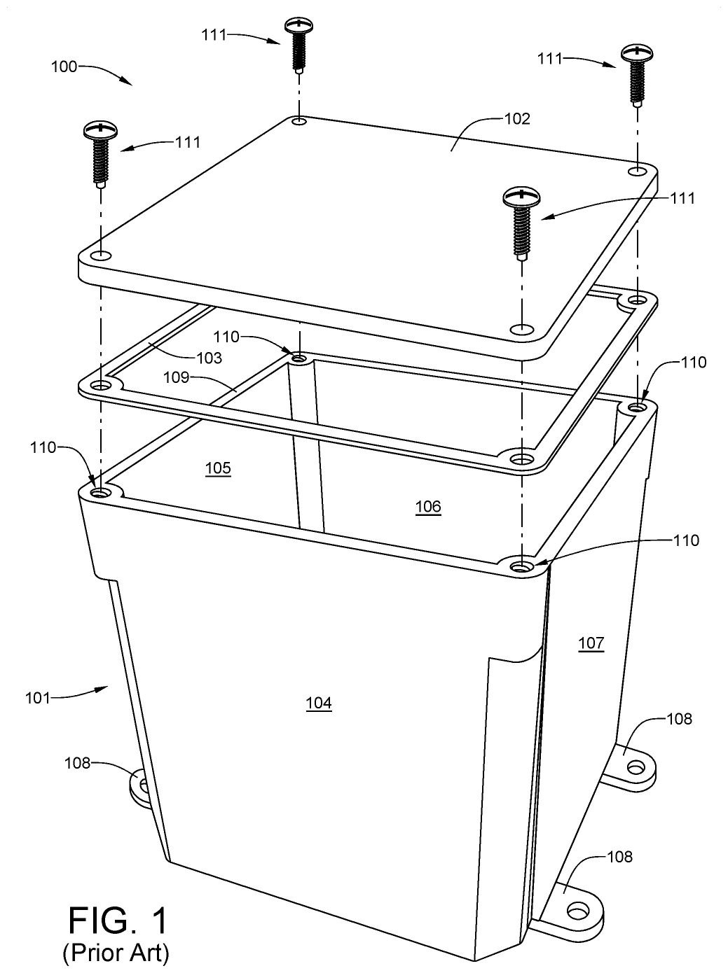

Referring now to FIG. 1, an invention prototype has been constructed using a Carlon® 4″×4″×4″ (10 cm×10 cm×10 cm) water-tight junction box 100 as a device housing. Although the size, shape and configuration of this Carlon® box is ideal for the application, the polyvinylchloride (PVC) material from which it is manufactured is not. PVC tends to deform at temperatures greater than 125 degrees Fahrenheit, and temperatures in excess of that amount can be reached if the product is exposed to direct sunlight. Thus, a similarly-shaped and configured water-tight junction box fabricated from a UV stabilized polymer resins, such as polypropylene (PP), high-density polyethylene (HDPE), polytetrafluoroethylene (PTFE), polyvinylidene fluoride (PVDF), acrylonitrile butadiene styrene (ABS) or Cycolac® (a mixture of ABS and polycarbonate) would be preferred for the housing of the device. Of these six thermoplastic resins, acrylonitrile butadiene styrene, polypropylene and high-density polyethylene are the most common and least expensive resins resins. Polypropylene is used extensively for automotive bumper fascia panels, high-density polyethylene is widely used for playground equipment, and ABS is used for 3D building materials, plumbing pipes and power tool housing. All three of these common thermoplastic polymer resins demonstrate high dimensionally stability when exposed to heat and sunlight.

Still referring to FIG. 1, the junction box (also referred to as the housing) 100 has a main body 101 that is shaped much like a large square shot glass. The main body 101 has four intersecting side panels 104, 105, 106 and 107, all of which intersect and are contiguous with a base panel (not visible in this view) that is colaminar with the four mounting lugs 108 (one of which is not visible in this view) at the base of the main body 101. The main body 101 has an upper perimetric rim 109. There is a threaded hole 110 at each corner of the perimetric rim 109. A top cover 102 is securable to the perimetric rim 109 with four stainless steel screws 111, with a laminar gasket 103 sandwiched between the perimetric rim 109 and a cover 102, thereby forming a water-tight compartment. Excluding the threaded holes 110 and the stainless steel screws 111, the junction box is bilaterally symmetrical about two vertically-oriented planes, one bisecting side panels 104 and 106, the other bisecting side panels 105 and 107. A number of apertures are made within the top cover 102 and within side panels 104, 105 and 106 in order to install various components of the parasitic emulator.

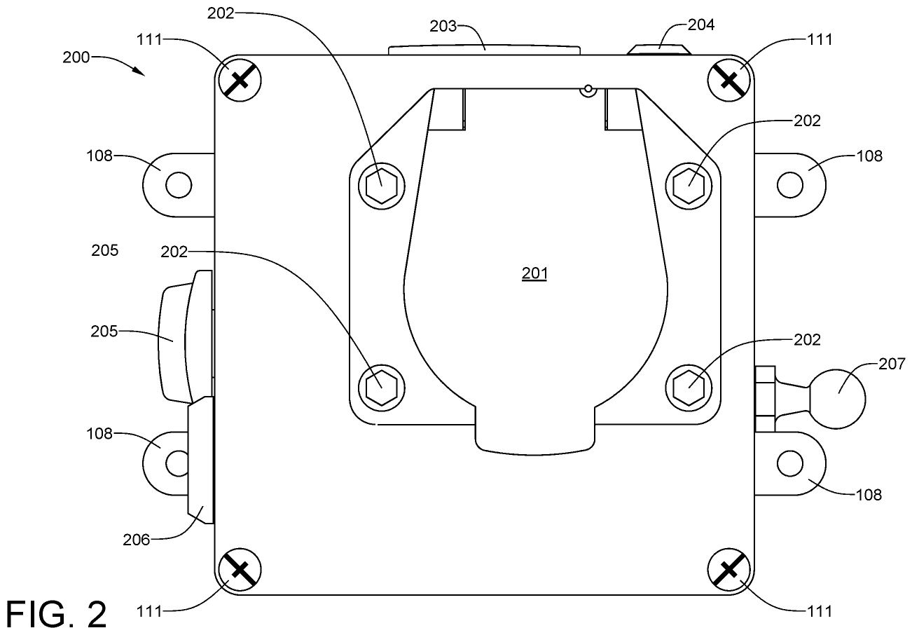

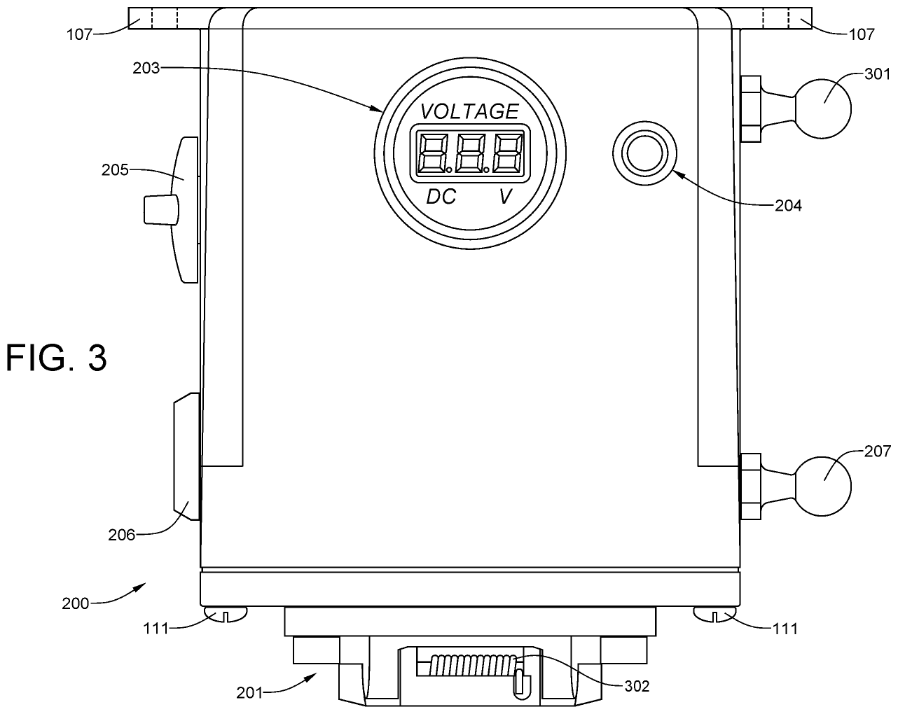

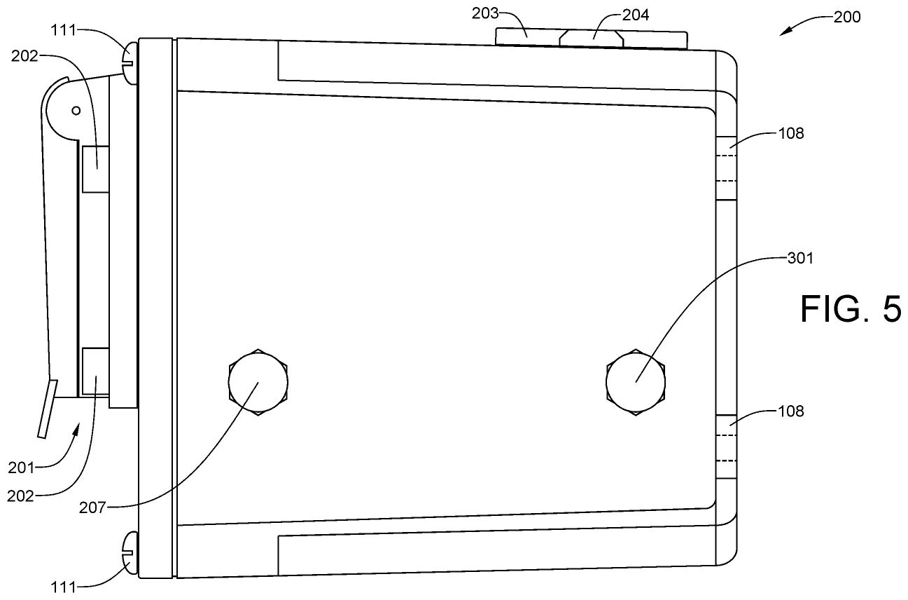

Referring now to FIG. 2, the parasitic emulator 200 includes a 7-way, RV-style trailer connector socket 201 that has been secured to the top cover 102 of the junction box (housing) 100 with four Allen head bolts 202. Washers and nuts are used to anchor the bolts 202 on the inside of the top cover 102. The connector socket 201 has a spring-loaded lift-up cover that shields the connector terminals from the weather. For the application of the present invention, the junction box 100 will, preferably, be oriented so that the top cover 102, and side panels 105 and 107 are oriented vertically, with side panel 104 functioning as the top panel of the device. 7-pole trailer connector sockets are available from numerous manufacturers. One such connector socket is available from Hopkins Towing Solutions as Hopkins 48485 7 Pole RV Blade Vehicle Connector. Another is available from Pollack by SMP as Pollack Replacement 7-Pole, RV-Style Trailer Connector Socket Item No. PK 1893. The parasitic emulator 200 also includes a 5-pole rotary switch 205 and a two-position ON/OFF key switch, both of which are mounted in panel 107. The two-position ON/OFF key switch is secured with a retaining nuts inside the main body 101, while the 5-pole rotary switch is secured with a retaining nut on the exterior of panel 107. The control knob of the 5-pole rotary switch 205 is all that is visible in this view, as the switch, itself, is located within the housing 100. The parasitic emulator 200 also includes a voltmeter 203 and a bicolor LED panel light 204, which are mounted within panel 204 and secured from within with retaining nuts. The parasitic emulator 200 also includes a pair of battery charger connector posts which are mounted in panel 105. Only the positive post 207 is visible in this view. The negative post (visible in FIGS. 3 and 5) is positioned precisely behind the positive post 207. Both posts are secured from within and electrical connections are made within the case. All four mounting lugs 108 are visible in this view, as are all four stainless steel cover-securing screws 111.

Referring now to FIG. 3, the voltage meter 201 and the bicolor LED panel light 204 are more clearly visible in this top plan view of the parasitic emulator 200. In addition, the negative charger connector post 301 is visible in this view, as are the positive charger connector post 207, the 5-pole rotary switch control knob 205, and the bezel of the two-position ON/OFF switch. The coil spring 302 used to maintain the lift-up cover of the 7-pole connector socket 201 in a normally closed position is visible in this view.

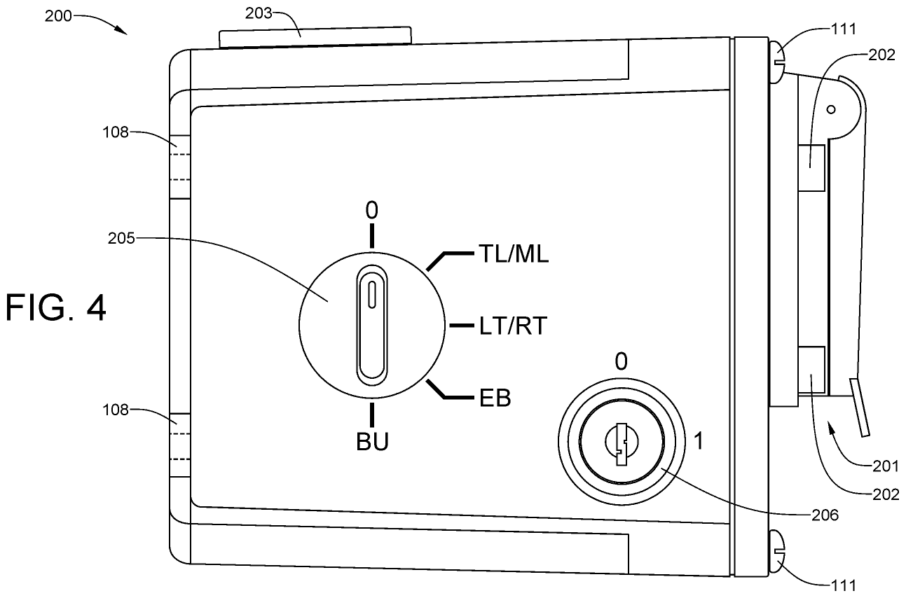

Referring now to FIG. 4, the control knob of the 5-pole rotary switch 205 is visible in this view of the left side of the parasitic emulator 200. There are five positions: OFF (0); tail lights and marker lights (TL/ML); left turn signal/right turn signal (LT/RT); electric brake (EB); and backup lights (BU). The 5-pole rotary switch 205 is indexed so that it clicks into a detent at each of the five rotary locations. The positions are also marked for the two-position key switch: OFF (0) and ON (1). As many trailers are not equipped with backup lights, the BU position may be used for another auxiliary electrical function.

Referring now to FIG. 5, both the positive battery charger post 207 and the negative battery charger post 301 are visible in this view of the right side of the parasitic emulator 200.

Referring now to the electrical circuit schematic diagram of FIG. 6, electrical connections between the various components are all made within the housing 100. A few of the components, such as diode D1, resistors R1 and R2, and two-prong flasher unit FL, are located entirely within the housing 100. Fuse F1, if it is a replaceable fuse or a resettable fuse, are also located entirely within the housing 100. However, a resettable circuit breaker will have a reset button that extends through an aperture in the housing so that a tester can reset it if it trips. All other components shown in the circuit schematic diagram of FIG. 6 (i.e., the socket 201, the voltmeter VM, switches S1 206 and S2 205, LEDs DR and DG, positive charging post 207 and ground charging post 301), are mounted within apertures in the housing so that they can be either accessed or viewed by the person performing the tests. It should also be understood that LEDs DR and DG are incorporated in a single three-lead component, as indicated by the broken line in the shape of a capsule that surrounds them.

Still referring to FIG. 6, operation of the parasitic emulator 200 will now be described. A trailer's electrical plug is inserted into the 7-way RV-type trailer plug socket 201, thereby connecting all of the trailer lighting circuits and the electric brake circuit to the parasitic emulator 200. The 7-way RV-type trailer plug socket 201 is a socket that is almost universally used for large trailers in the United States, including travel trailers and fifth-wheel trailers. The socket 201 has six resilient, laminar folded terminals that are tangent to and equiangularly spaced about a circle (not shown). The socket also has a seventh laminar U-shaped terminal which is positioned at the center of the circle. The trailer plug has six laminar spade-type terminals equiangularly spaced about a circle, each of which mates with one of the six folded terminals of the socket 201, and a central cylindrical terminal that mates with the U-shaped terminal of the socket 201. When a trailer's plug is inserted into the plug socket 201, the trailer's battery is connected to the electrical circuitry 600 of the parasitic emulator 200 via the ground (GD) and positive (12V) terminals (terminals 1 and 4, respectively) of the socket 201. Electrical circuitry of the parasitic emulator 200 is protected by either a replaceable 10-amp fuse F1 or a 10-amp circuit breaker that is either automatically or manually resettable. In order to test the circuits various trailer circuits, the keyed ON/OFF switch SW 206 is switched to ON. The voltmeter VM 203 will show the current trailer battery voltage. If battery voltage is within a usable range of between about 11.5-15 VDC, the green LED (DG), which is rated for 10.6 VDC, will turn on. LED DG is fed through resistor R1, which has a value of about 150 ohms. If the battery voltage is marginal (i.e., within a range of about 5-11.5 VDC, the red LED DR will illuminate. LED DR is fed through resistor R2, which has a value of about 220 ohms. LED DR is rated at about 4.6 VDC. If battery voltage is below about 5 VDC, then not even the red LED DR will turn on. Starting with the rotary switch SW 205 OFF, the knob of that switch is rotated to the T/M position so that battery power is fed to terminal 7 of the socket 201. A voltage drop will show on the voltmemter VM 203. If the trailer is equipped with incandescent light bulbs, a voltage drop of about 1.5 to 2.0 volts can be expected. Of course, if LED bulbs are used, the voltage drop will be greatly reduced. In addition, each of the marker and tail lights may be visually verified to be functional. Next, the LT/RT position is selected, thereby feeding battery voltage to terminals 5 and 6 of the socket 201. The parasitic emulator 200 includes a two-prong flasher unit FL that will flash both left and right turn light circuits. The brake lights use the same circuit as the turn signal circuits. Thus if both left and right turn signal lights flash, then the turn signal light and brake circuit light circuits are functional. In order to test the electric brake circuit, the EB position of the rotary switch SW205 is selected, thereby sending battery power to terminal 2 of the socket 201. When the EB position is selected, the tester should hear a click as the brakes are applied. If the trailer wheels are jacked off the ground, they will be impossible to rotate by hand. A voltage drop of about 2.3-2.7 volts can be expected for most electric brake systems. Finally, in the backup (BU) position, battery power is sent to terminal 7 of the socket 201, thereby enabling the tester to check functionality of the backup lights. Verification of functionality of all circuits can be checked using a voltage drop on the voltmeter 203 or by visual verification. If the trailer battery needs charging, charger outputs can be clipped to positive post 207 and to negative post 301. A diode D1 prevents trailer battery voltage from interfering with medical electrical devices, such as a pacemaker, worn by a tester, as voltage can flow only into the circuit (e.g., from a battery charger), not out. If a trailer does not have an on-board battery, its electrical circuits may still be testing by connecting the output cables of a 12 VDC charger to the positive charging post 207 and to the negative charging post 301. In the event such a trailer does not have an electrical plug that is compatible with the socket 201 of the parasitic emulator 200, adapters are available from numerous sources that will enable the connection of the non-mating trailer plug to the socket 201.

The trailer plug can remain plugged into the socket 201. The keyed ON/OFF switch SW 206 ensures that vandals cannot run down the trailer battery. By storing the trailer plug with it inserted into the socket 201, the plug is protected from the elements. The interior of the parasitic emulator 200 is preferably watertight so that electrical components and connections, all of which are made within the housing 100, are also protected from the elements.

When parking the trailer, traditionally the user will need to keep the truck attached to the trailer to keep from rolling before placing the blocks. With this apparatus the truck can be disengaged before placing these blocks by engaging the electric brake system using the parasitic emulator 200. The parasitic emulator 200 can also be mounted to the trailer with security screws to deter theft. In addition, the parasitic emulator 200 is intended to be made available through both a trailer factory install program or as an after-market add-on component.

Although only a single embodiment of the parasitic emulator 200 has been shown and described, it will be obvious to those having ordinary skill in the art that changes and modifications may be made thereto without departing from the scope and the spirit of the invention as hereinafter claimed.

What is claimed is:

1. A parasitic emulator for testing electrical circuits on a trailer having a 7-way electrical connector plug and an onboard electro-chemical battery having both positive and ground terminals, said parasitic emulator comprising:
a housing;
a seven-way RV-type connector socket mounted on an exterior surface of the housing into which mates with the 7-way electrical connector plug of the trailer, said mating of the connector plug with the connector socket providing both a positive connection and a ground connection to the trailer battery; and
a selector switch mounted on an exterior surface of the housing, which receives battery power from one of seven terminals in the 7-way electrical connector socket, and which can selectively provide power to other terminals in the 7-way electrical connector socket associated with various electrical circuits on the trailer so that each of those circuits can be tested for functionality when the connector plug is inserted into the connector socket.

2. The parasitic emulator of claim 1, which further comprises a voltmeter mounted on an exterior surface of the housing, which provides a readout of trailer battery voltage.

3. The parasitic emulator of claim 1, which further comprises a first light-emitting-diode (LED) circuit which will illuminate a first LED when the first LED circuit is connected to trailer battery power and trailer battery voltage is sufficient for trailer circuit testing to proceed.

4. The parasitic emulator of claim 3, which further comprises a second LED circuit which will illuminate a second LED when the second LED circuit is connected to trailer battery power and trailer voltage is insufficient for trailer circuit testing to proceed.

5. The parasitic emulator of claim 1, which further comprises positive and ground charging posts mounted on an exterior surface of the housing, said ground charging post providing an electrical connection to the trailer battery's ground terminal through the mating of the connector plug and the connector socket, and said positive charging post providing an electrical connection to the trailer battery's positive terminal through the same mating of the connector plug and the connector socket.

6. The parasitic emulator of claim 5, which further comprises a diode in series with the positive charging post and a positive terminal of the connector socket, said diode preventing a discharge of voltage from the positive charging post that might damage electrically-powered medical devices, such as a pacemaker, that a tester might be wearing.

7. The parasitic emulator of claim 1, which further comprises a keyed ON/OFF switch positioned between a positive terminal of the connector socket and a voltage input to the selector switch.

8. The parasitic emulator of claim 7, which further comprises a current protection device positioned between the ON/OFF switch and the positive terminal of the connector socket, said current protection device being selected from the group consisting of a replaceable fuse, an automatically resetting fuse, and a circuit breaker.

9. A parasitic emulator for testing electrical circuits on a trailer having a 7-way electrical connector plug and an onboard electro-chemical battery having both positive and ground terminals, said parasitic emulator comprising:
a housing;
a seven-way RV-type connector socket mounted on an exterior surface of the housing into which mates with the 7-way electrical connector plug of the trailer, said mating of the connector plug with the connector socket providing both a positive connection and a ground connection to the trailer battery;
a rotary selector switch mounted on an exterior surface of the housing, which receives battery power from one of seven terminals in the 7-way electrical connector socket, and which can selectively provide power to other terminals in the 7-way electrical connector socket associated with various electrical circuits on the trailer so that each of those circuits can be tested for functionality when the connector plug is inserted into the connector socket;
positive and ground charging posts mounted on an exterior surface of the housing, said ground charging post providing an electrical connection to the trailer battery's ground terminal through the mating of the connector plug and the connector socket, and said positive charging post providing an electrical connection to the trailer battery's positive terminal through the same mating of the connector plug and the connector socket;
a diode in series with the positive charging post and a positive terminal of the connector socket, said diode preventing a discharge of voltage from the positive charging post that might damage electrically-powered medical devices, such as a pacemaker, that a tester might be wearing; and
a keyed ON/OFF switch positioned between a positive terminal of the connector socket and a voltage input to the selector switch.

10. The parasitic emulator of claim 9, which further comprises a voltmeter mounted on an exterior surface of the housing, which provides a readout of trailer battery voltage.

11. The parasitic emulator of claim 9, which further comprises a first light-emitting-diode (LED) circuit which will illuminate a first LED when the first LED circuit is connected to trailer battery power and trailer battery voltage is sufficient for trailer circuit testing to proceed.

12. The parasitic emulator of claim 11, which further comprises a second LED circuit which will illuminate a second LED when the second LED circuit is connected to trailer battery power and trailer voltage is insufficient for trailer circuit testing to proceed.

13. The parasitic emulator of claim 12, wherein said voltmeter and said first and second LEDs are mounted on a top exterior surface of the housing so that they are readily visible by a tester.

14. The parasitic emulator of claim 9, which further comprises a current protection device positioned between the ON/OFF switch and the positive terminal of the connector socket, said current protection device being selected from the group consisting of a replaceable fuse, an automatically resetting fuse, and a circuit breaker.

15. The parasitic emulator of claim 9, wherein said housing includes a plurality of mounting lugs which enable the parasitic emulator to be permanently mounted on the trailer.

16. A parasitic emulator for testing electrical circuits on a trailer having a 7-way electrical connector plug and an onboard electro-chemical battery having both positive and ground terminals, said parasitic emulator comprising:
a watertight housing;
a seven-way RV-type connector socket mounted on an exterior surface of the housing into which mates with the 7-way electrical connector plug of the trailer, said mating of the connector plug with the connector socket providing both a positive connection and a ground connection to the trailer battery;
a rotary selector switch mounted on an exterior surface of the housing, which receives battery power from one of seven terminals in the 7-way electrical connector socket, and which can selectively provide power to other terminals in the 7-way electrical connector socket associated with various electrical circuits on the trailer so that each of those circuits can be tested for functionality when the connector plug is inserted into the connector socket;
a voltmeter mounted on an exterior surface of the housing, which provides a readout of trailer battery voltage;
positive and ground charging posts mounted on an exterior surface of the housing, said ground charging post providing an electrical connection to the trailer battery's ground terminal through the mating of the connector plug and the connector socket, and said positive charging post providing an electrical connection to the trailer battery's positive terminal through the same mating of the connector plug and the connector socket; and
a diode in series with the positive charging post and a positive terminal of the connector socket, said diode preventing a discharge of voltage from the positive charging post that might damage electrically-powered medical devices, such as a pacemaker, worn by a tester.

17. The parasitic emulator of claim 16, which further comprises a keyed ON/OFF switch positioned between a positive terminal of the connector socket and a voltage input to the selector switch.

18. The parasitic emulator of claim 17, which further comprises a current protection device positioned between the ON/OFF switch and the positive terminal of the connector socket, said current protection device being selected from the group consisting of a replaceable fuse, an automatically resetting fuse, and a circuit breaker.

19. The parasitic emulator of claim 16, which further comprises a first and second light-emitting-diode (LED) circuits, said first LED circuit illuminating a first LED when the first LED circuit is connected to trailer battery power and trailer battery voltage is sufficient for trailer circuit testing to proceed, and said second LED circuit illuminating a second LED when the second LED circuit is connected to trailer battery power and trailer voltage is insufficient for trailer circuit testing to proceed.

20. The parasitic emulator of claim 16, wherein said housing includes a plurality of mounting lugs which enable the parasitic emulator to be permanently mounted on the trailer.
